(19) United States
(12) Patent Application Publication
(10) Pub. No.: US 2008/0074590 A1
(43) Pub. Date: Mar. 27, 2008

(54) COLOR FILTER SUBSTRATE AND LIQUID CRYSTAL DISPLAY APPARATUS HAVING THE SAME

(76) Inventor: Young-Bae Jung, Hwaseong-si (KR)

Correspondence Address: F. CHAU & ASSOCIATES, LLC, 130 WOODBURY ROAD, WOODBURY, NY, 11797, US

(21) Appl. No.: 11/742,017

(22) Filed: Apr. 30, 2007

(30) Foreign Application Priority Data
Sep. 21, 2006 (KR) 2006-91624

(51) Int. Cl. G02F 1/1335; G02B 5/22; G03F 1/00

(52) U.S. Cl. 349/109; 349/106; 359/885; 430/7

(57) ABSTRACT

A color filter substrate including first areas and second areas includes a base substrate, a color filter layer and a planarization layer formed in the second areas, and a transparent electrode. The color filter layer includes a plurality of color filters formed in the first and second areas. At least one of the color filters formed in a second area has an opening that exposes a portion of the base substrate The planarization layer 130 may be formed by a one-step exposing process that uses a mask having a transparent portion, a translucent portion and a shading portion. Therefore, the process may be simplified, and a display quality of a display apparatus may be improved.

### CROSS-REFERENCE TO RELATED APPLICATION

This application claims priority to Korean Patent Application No. 2006-91624 filed on Sep. 21, 2006, the contents of which are herein incorporated by reference in their entirety.

### BACKGROUND OF THE INVENTION

1. Technical Field

The present invention relates to a color filter substrate and, more particularly, to a color filter substrate capable of improving display properties, and a display apparatus having the color filter substrate.

2. Discussion of the Related Art

A transflective type liquid crystal display (“LCD”) apparatus displays an image in a reflection mode using external light when the external light is sufficient to display the image, and displays an image in a transmission mode using, for example, internal light generated by consuming self-charged electric energy when the external light is not sufficient to display the image.

The transflective type LCD apparatus includes an LCD panel comprising an array substrate, a color filter substrate facing the array substrate and liquid crystal interposed between the array and color fitter substrates.

The array substrate includes a transmission electrode and a reflection electrode. A reflection area refers to an area where the reflection electrode is formed on the transmission electrode, and a transmission area refers to an area where the reflection electrode is not formed on the transmission electrode. The color filter substrate includes a color filter and a common electrode. The color filter is formed in red (R), green (G) and blue (B) color pixels, respectively. The color filter substrate is combined with the array substrate.

When the transflective type LCD apparatus operates in the reflection mode, the external light goes through a first pathway, for example, sequentially passing through a color filter, a common electrode, liquid crystal, a reflection electrode, then again through the liquid crystal, the common electrode and the color filter. When the transflective type LCD apparatus operates in the transmission mode, the external light goes through a second pathway, for example, sequentially passing through a pixel electrode, liquid crystal, a common electrode, and a color filter.

As mentioned above, the external light passes through the color filter twice in the reflection mode, and hence there is loss of light in the reflection mode. To prevent the loss and improve reflectivity, a portion of the color filter in the reflection area is removed. The removed portion of the color filter causes a step difference when the color filter is coated with an organic material. Accordingly, a cell gap of the reflection area is different from a cell gap in the transmission area. When the cell gap is different from a designed value, a yellowish image is displayed or contrast ratio deteriorates.

### SUMMARY OF THE INVENTION

Embodiments of the present invention provide a color filter substrate capable of improving display properties, an LCD apparatus having the color filter substrate, and methods of manufacturing the color filter substrate and the LCD apparatus having the color fitter substrate.

A color fitter substrate, according to an example embodiment of the present invention, includes a plurality of first and second areas, a base substrates a color fitter layer formed on the base substrate, a planarization layer formed in the second areas, and a transparent electrode covering the color filters formed in the first areas and the planarization layer formed in the second areas. The color filter layer includes a plurality of color filters formed in the first and second areas. At least one of the color filters formed in a second area has an opening that exposes a portion of the base substrate. The planarization layer has a uniform height with respect to the base substrate.

The planarization layer may comprise an organic material. The opening may be circular or quadrilateral in shape. The size of the opening may be equal to or less than half the size of the color filter formed in the second area.

The color filters formed in the first and second areas include red (R), green (G) and blue (B) color filters, respectively, and each of the R, G and B color filters formed in the second areas may include an opening that partially exposes the base substrate in the second area. The size of the openings respectively formed in the red (R), green (G) and blue (B) color filters in the second areas may be different from each other. The size of the opening formed in the red (R) color filter may be larger than the size of the opening formed in the blue (B) color filter, and the size of the opening formed in the green (G) color filter may be larger than the size of the opening formed in the red (R) color filter. Additionally, the size of the openings respectively formed in the red (R), green (G) and blue (B) color filters may be the same, and numbers of the openings respectively formed in the R, G and B color filters may be different from each other. The number of the opening formed in the red (R) color filter may be more than the number of the openings formed in the blue (B) color filter, and the number of the openings formed in the green (G) color filter may be more than the number of the openings formed in the red (R) color filter

Additionally, the thicknesses of the R, G and B color filters formed in the second areas may be different from each other. The red (R) color filter may be thinner than the blue (B) color filter, and the green (G) color filter may be thinner than the red (R) color filter.

A first light that sequentially passes through the transparent electrode the color filter layer and the base substrate is provided to the first areas, and a second light that sequentially passes through the base substrate, the color filter layer, the transparent electrode, the color filter layer and the base substrate is provided to the second areas,

In a method of manufacturing a color filter substrate including a first area and a second area according to an example embodiment of the present invention, the method includes forming a color filter layer on the base substrate, forming an opening in the color filter formed in the second area, coating the color filter layer with an organic material, exposing the organic material to light with a mask disposed over the organic material forming a planarization layer in the second area by developing the organic material and forming a transparent electrode on the planarization layer and the color filter layer, respectively. The opening partially exposes the base substrate. The planarization layer has a uniform height with respect to the base substrate.

The mask includes a transparent portion transmitting light, a translucent portion partially transmitting light, and a shading portion at least substantially shutting light out. An optical transmissivity of the translucent portion may be in a range from about 10% to about 30%. The mask is disposed so that the shading portion corresponds to the opening of the color filter; the translucent portion corresponds to a region where the opening is not formed in the second area, and the transparent portion corresponds to the first area. The transparent portion the translucent portion and the shading portion may be formed at layers different from each other, or the transparent portion, the translucent portion and the shading portion may be formed at the same layer.

The transparent electrode may cover the color filter formed in the first area and the planarization layer formed in the second area, respectively.

### BRIEF DESCRIPTION OF THE DRAWINGS

Exemplary embodiments of the present invention can be understood in more detail from the following descriptions taken in conjunction with the accompanying drawings in which:

FIG. 1 is a cross-sectional view illustrating a color filter substrate according to an example embodiment of the present invention.

FIG. 2 is a plan view of the color filter illustrated in FIG. 1.

FIG. 3 is a plan view illustrating a color filter according to an example embodiment of the present invention;

FIGS. 4, 5 and 6 are cross-sectional views illustrating a method of manufacturing a color filter substrate according to an example embodiment of the present invention; and

FIG. 7 is a cross-sectional view illustrating a transflective type LCD apparatus having a color filter substrate according to an example embodiment of the present invention.

### DETAILED DESCRIPTION OF EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. It will be understood that when an element is referred to as being “on” or “onto” another element, it may be directly on the other element or intervening elements may also be present. Like reference numerals may refer to similar or identical elements throughout.

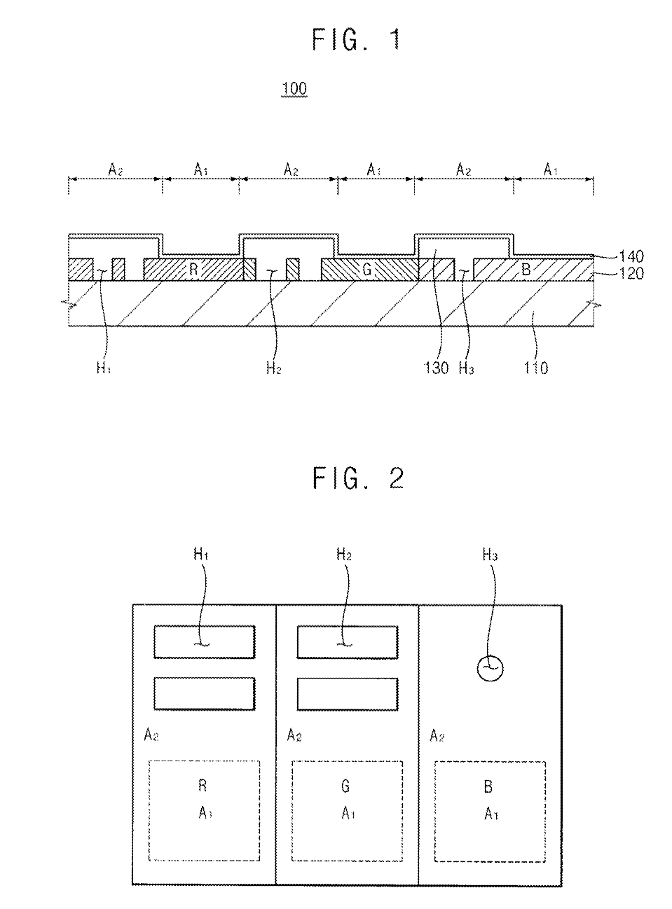

FIG. 1 is a cross-sectional view illustrating a color filter substrate according to an example embodiment of the present invention FIG. 2 is a plan view of the color filter illustrated in FIG. 1.

Referring to FIG. 1 a color filter substrate 100 includes a base substrate 110, a color filter layer 120 formed on the base substrate 110, a planarization layer 130 formed on the color filter layer 120 and a common electrode 140 formed on the planarization layer 130 and the color filter layer 120. The color filter substrate 100 includes a plurality of color pixels and includes first areas A1 and second areas A2 adjacent to the first areas A1.

A first light that sequentially passes through the common electrode 140, the color filter layer 120 and the base substrate 110 is provided to the first area A1, and a second light that sequentially passes through the base substrate 110, the color filter layer 120, the common electrode 140, and again through the color filter layer 120 and the base substrate 110 is provided to the second area A2. Accordingly, the first light provided to the first area A1 passes through the color filter layer 120 only once, and the second light provided to the second area A2 passes through the color filter layer 120 twice.

The color filter layer 120 includes a red color filter (R color filter), a green color filter (G color filter) and a blue color filter (B color filter) that are formed at each of the corresponding color pixels. The R, G and B color filters are formed in the first and second areas A1 and A2.

Referring to FIG. 1, first holes H1 are formed in the R color filter in the second area A2 to expose the base substrate 110. Second holes H2 larger than the first holes H1 are formed in the G color filter in the second area A2 to expose the base substrate 110. Accordingly, the G color filter is smaller than the R color filter in the second area A2. A third hole H3 smaller than the portion removed by first holes H1 is formed in the B color filter in the second area A2 to expose the base substrate 110. Accordingly, the area of the B color filter is larger than that of the G color filter or that of the R color filter in the second area A2. It is to be understood that holes H1, H2, H3 may be formed as one or more holes in the R, G and B color filters.

As shown in FIG. 1, the R, G and B color pixels in the first areas A1 are entirely covered with the corresponding color filters, and the R, G and B color pixels in the second areas A2 are partially exposed through the first second and third holes H1, H2 and H3. As a result, a color reproducibility difference of the RGB color pixels between the first areas A1 and the second areas A2 may be reduced.

When the above-mentioned holes are not formed in the R, G and B color filters in the second areas A2, the x-y color coordinates of the R, G and B color pixels in the second area A2 are different from those of the corresponding color pixels in the first areas A1. This is due to the color reproducibility of the RGB color pixels in the second areas AS being different from that in the first areas A1. Therefore, the first, second and third holes H1, H2 and H3 are respectively formed in the R, G and B color filters in the second areas A2 to compensate for the above-mentioned color reproducibility differences of the RGB color pixels between the first areas A1 and the second areas A2.

Additionally, the sizes of the first, second and third holes H1, H2 and H3 are different from each other to compensate for a color visibility difference and a brightness difference among the R, G and B color pixels.

Generally, the color visibility and brightness of each of the respective R, G and B color pixels is different.

Among the R, G and B color pixels, the B color pixel whose wavelength band is close to an ultraviolet ray has less color visibility and brightness than the R and G pixels. The color visibility and brightness of the R color pixel, whose wavelength band is close to an infrared ray, are higher than those of the B color pixel. The G color pixel whose wavelength band is close to a visible ray has the highest color visibility and brightness, among the R, G and B color pixels.

To compensate for the color visibility and brightness differences among the R, G and B color pixels, the sizes of the first, second and third holes H1. H2 and H3 formed in the second areas are different from each other. For example, when a total size, that is a sum of the sizes of the first hole H1 and the R color filter formed in the second area A2, is ‘100’, the first hole H1 occupies an area of about 13% with respect to the total size. Similarly, the second hole H2 occupies an area of about 21% with respect to a sum of the sizes of the second hole H2 and the G color fitter formed in the second area A2. Also, the third hole H3 occupies an area of about 6% with respect to a sum of the sizes of the third hole H3 and the B color filter formed in the second area A2.

The variation rate of the color coordinates of the G color pixel depending on the size of the G color pixel is less than that of the R color pixel or B color pixel. Therefore, the area of the G color filter may be further reduced to improve optical efficiency. As a result, in alternate embodiments, the second hole(s) H2 formed in the G color filter may be formed so that the size thereof is larger than 21% of the total size.

The area of the G color filter is smaller than that of the R color filter and the area of the R color filter is smaller than that of the B color filter, because the size of the second hole(s) H2 being larger than that of the first hole(s) H1 and the size of the first hole(s) H1 being larger than that of the third hole(s) H3. As a result, the color visibility and brightness differences between the R, G and B color pixels in the second area A2 may be reduced.

In an example embodiment as shown in FIG. 2, two first holes H1 may be formed in the R color filter, and two second holes H2 larger than the first holes H1 may be formed in the G color filter. In the B color filter, a third hole H3 smaller than the first holes H1 is formed. Accordingly the sizes of the R, G and B color filters in the second areas A2 are different from each other.

Even though the number of the first holes H1 is equal to the number of the second holes H2, the size of the R color filter is larger than that of the G color filter because the size of the second holes H2 is larger than that of the first holes H1.

In FIGS. 1 and 2, the R, G and B color pixels have individual sizes different from each other. In an alternative embodiment, only one of the R, G and B color filters is different in size from the other two color filters. For example, the R and G color filters may have substantially the same size, and the size of the B color filter may be smaller than that of the R and G color filters. In another embodiment, the R and B color filters may have substantially the same size, and the size of the G color filter may be larger than that of the R and B color filters.

The color filter substrate 100 includes the planarization layer 130 for removing a step difference between the base substrate 110 and the color filter layer 120. More particularly, the planarization layer 130 removes a step difference between a portion of the base substrate 110 exposed through the first, second and third holes H1, H2 and H3 respectively, and a portion adjacent to the first, second and third holes H1, H2 and H3, respectively.

The planarization layer 130 is formed on the color filter layer 120 in the second area A2 and portions of the base substrate 110 exposed through the first, second and third holes H1, H2 and H3, respectively. The planarization layer 130 may be formed of a photosensitive organic insulating layer comprising, for example, an acrylic resin.

The common electrode 140 is formed on the planarization layer 130 and portions of the color filter layer 120 not covered by the planarization layer 130. The common electrode 140 may comprise a transparent conductive material such as indium tin oxide (ITO), indium zinc oxide (IZO), or the like.

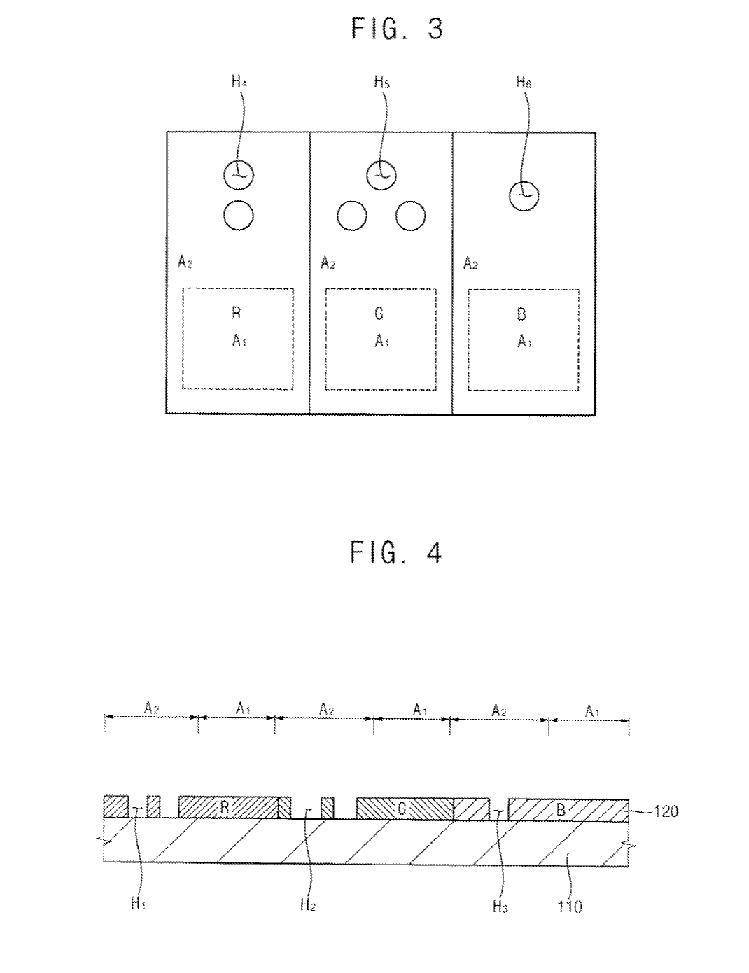

FIG. 3 is a plan view illustrating a color filter according to an example embodiment of the present invention.

Referring to FIG. 3 two first holes H4 are formed at the R color pixels and three second holes H5 are formed at the G color pixel. At the B color pixel, a third hole H6 is formed. The second holes H5 and the third hole H6 may have substantially the same size as the first holes H4.

Even though the respective sizes of the first, second and third holes H4, H5 and H6 are substantially the same, the respective areas of the R, G and B color filters are different from each other because respective numbers of the holes are different from each other. Herein, the area of the G color filter is the smallest among the R, G and B color filters because the number of the second holes H5 formed at the G color pixel is the most, and the area of the B filter is the smallest among the R, G and B color filters because the number of the third holes H6 formed at the B color pixel is the least.

Although a structure that the color reproducibility difference between the first and second areas A1 and A2 or the color visibility difference among the R, G and B color pixels is adjusted by forming at least one hole at the R, G and B color pixels as described in FIGS. 1 to 3, the color reproducibility difference or the color visibility difference may also be compensated for by adjusting respective thicknesses of the R, G and B color filters.

For example, the R, G and B color filters in the first area A1 may be thinner than the R, G and B color filters in the second area A2, respectively, to compensate for color reproducibility differences between the first and second areas A1 and A2.

For examples the B color filter, having less color visibility, may be the thickest among the R, G and B color filters in the second area A2. The R color filter, having higher color visibility, may be thinner than the B color filter, and the G color filter, having even higher color visibility, may be the thinnest among the R, G and B color filters. Accordingly, the color visibility differences among the R, G and B color pixels may be compensated for by adjusting the respective thicknesses of the R, G and B color filters.

Also, the color visibility differences among the color pixels may be adjusted by forming at least one slit substantially parallel with the color pixels, instead of the holes.

FIGS. 4, 5 and 6 are cross-sectional views illustrating a method of manufacturing a color filter substrate according to an example embodiment of air the present invention.

Referring to FIG. 4, the color filter layer 120 comprising R (red), G (green) and B (blue) color filters is formed on a base substrate 110 of the color filter substrate. The color filter substrate includes first areas A1 and second areas A2.

In the R, G and B color filters in the second areas A2, first, second and third holes H1, H2 and H3 are respectively formed to partially expose the base substrate 110. Accordingly, each of the R, G and B color filters in the second area A2 is partially removed by the first, second and third holes H1, H2 and H3.

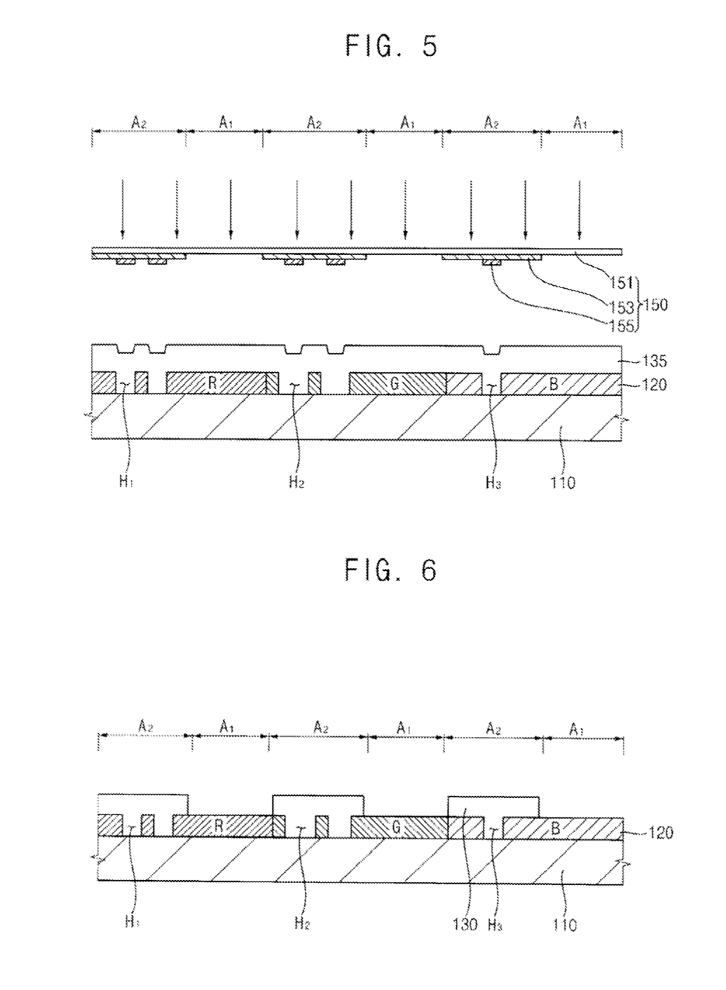

Referring to FIG. 5, the color filter layer 120 and the base substrate 110 that is partially exposed through the first, second and third holes H1, H2 and H3 are coated with an organic insulating layer 135 having a predetermined thickness. A surface of the organic insulating layer 135 is not uniform due to the step difference between the color filter layer 120 and the base substrate 110. That is, some recesses may be formed on the surface of the organic insulating layer 135 due to the step differences.

Next, a mask 150 having patterns corresponding to the recesses formed on the surface of the organic insulating layer 135 is disposed over the organic insulating layer 135. The mask 150 includes a transparent substrate 151, a translucent layer 153 disposed on the transparent layer 151, and a shading layer 155 disposed on the translucent layer 153.

The transparent layer 151 may comprise a transparent material, for example, such as quartz. The transparent layer 151 may transmit substantially all of the light incident from a rear of the mask 150. The translucent layer 153 may comprise a transparent material, for example, such as molybdenum silicon (MoSi). An optical transmissivity of the translucent layer 153 may be in a range from about 10% to about 30%, and thus the translucent layer 153 partially transmits the light passing through the C)s transparent layer 151. The shading layer 155 may comprise chromium (Cr), for example.

The shading layer 155 of the mask 150 is disposed corresponding to the first, second and third holes H1, H2 and H3 of the R, G and B color filters in the second areas A2, and the translucent layer 153 of the mask 150 is disposed corresponding to the second areas A2. Accordingly, the portions of the translucent layer 153 not covered by the shading layer correspond to regions where the first, second and third holes H1, H2 and H3 in the second areas A2 are not formed, and the portions of the transparent layer 151 not covered by the translucent and shading layers 153, 155 correspond to the first areas A1 of the color filter substrate,

Although the transparent layer 151, the translucent layer 153 and the shading layer 155 are respectively formed at individual layers different from each other in this embodiment as illustrated in FIG, 5, the mask may include a transparent portion, a translucent portion and a shading portion that are formed at the same layer in another embodiment.

When the organic insulating layer 135 is exposed to light through an exposing process with the mask 150 disposed as mentioned above and the air light-exposed organic insulating layer 135 is developed, a planarization layer 130 remains on the base substrate 110 corresponding to the second areas A2 of the color filter substrate, as illustrated in FIG. 6 Accordingly, the step differences caused by removing a portion of the color filter layer 120 may be eliminated by the planarization layer 130. That is, the height of the second areas A2 may become uniform because of the planarization layer 130. Therefore, a cell gap of the second areas A2 may become uniform, and thus a defect or a fault caused by a non-uniform cell gap of the second areas A2 may be eliminated.

The planarization layer is formed of an organic material. Alternatively, the planarization layer may be formed of an inorganic material such as silicon nitride (SiNx), silicon oxide (SiOx), etc.

Additionally, although holes are formed in each of the R, G and B color filters in FIGS. 4 to 6, holes may be formed in less than all of the R, G and B color filters. In an alternative embodiment, slits may be formed in the R, G and/or B color filters instead of the holes.

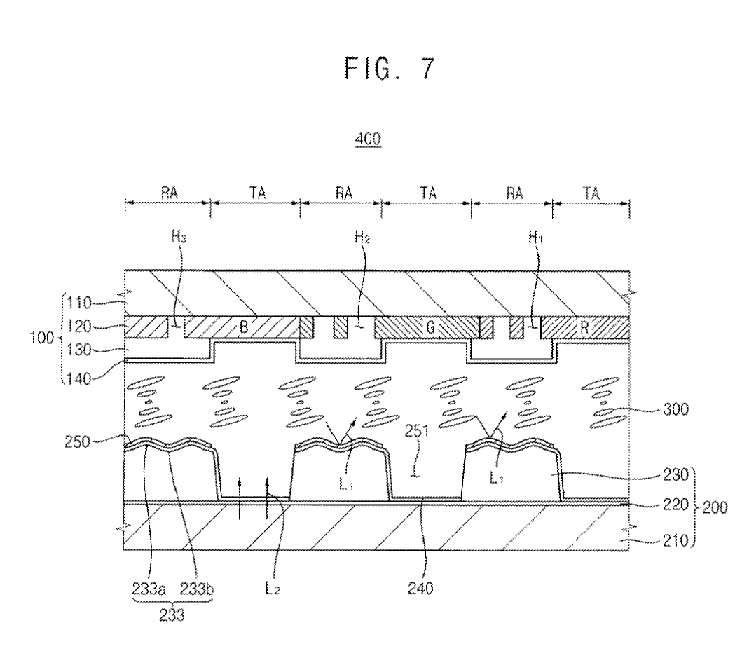

FIG. 7 is a cross-sectional view illustrating a transflective type LCD apparatus having a color filter substrate according to an example embodiment of the present invention.

Referring to FIG. 7, a transflective type LCD apparatus 400 includes an array substrate 200, a color filter substrate 100 opposite to the array substrate 200 and a liquid crystal layer 300 interposed between the array substrate 200 and the color filter substrate 100.

The array substrate 200 includes a first base substrate 210, a gate insulating layer 220 formed on the first base substrate 210, an organic insulating layer 230 formed on the gate insulating layer 220, a transmission electrode 240 and a reflection electrode 250. The array substrate 200 includes reflection areas RA and transmission areas TA. A plurality of TFTs (not shown) is formed on the first base substrate 210. The organic insulating layer 230 includes a photosensitive organic insulating layer, for example, such as acryl resin, etc.

The organic insulating layer 230 covers the TFTs. The organic insulating layer 230 is formed at an area corresponding to the reflection areas RA, and is open at an area corresponding to the transmission areas TA to expose the gate insulating layer 220 formed on the first base substrate 210. A plurality of concavo-convex portions 233 may be formed on an upper surface of the organic insulating layer 230 corresponding to the reflection areas RA. The concavo-convex portion 233 includes a convex portion 233a and a concave portion 233b.

The transmission electrode 240 having a substantially uniform thickness is formed on both the organic insulating layer 230 and the exposed portion of the gate insulating layer 220 formed on the first base substrate 210: which is the portion where the organic insulating layer 230 is not formed. The transmission electrode 240 may be formed of indium tin oxide (ITO) or indium zinc oxide (IZO), for example. The reflection electrode 250 having a air substantially uniform thickness is formed on the transmission electrode 240. The reflection electrode 250 has a transmission window 251 partially exposing the transmission electrode 240. The transmission window 251 is formed corresponding to the transmission areas TA.

Accordingly, a cell gap of the transmission areas TA is different from that of the reflection areas RA. For example, the cell gap of the transmission areas TA is approximately twice that of the reflection areas RA.

The cell gap of a reflection area RA is the distance between the common electrode 140 of the color filter substrate 100 and the reflection electrode 250 of the array substrate 200. The cell gap of a transmission area TA is the distance between the common electrode 140 and transmission electrode 240.

The reflection electrode 250 may be formed of for example, a single layer including aluminum-neodymium (AlNd), or a double layer including aluminum-neodymium (AlNd) and molybdenum-tungsten (MoW).

A contact hole (not shown) may be formed in the organic insulating layer 230 to expose a drain electrode of the TFT (not shown). When the contact hole is formed in the organic insulating layer 230, the transmission electrode 240 and reflection electrode 250 are electrically connected to the drain electrode of the TFT via the contact hole.

The reflection electrode 250 formed in the reflection areas RA reflects an external light L1 incident through the color filter substrate 100 back to the exterior through the color filter substrate 100. As a result, an image can be displayed. Additionally, in the transmission areas TA, an internal light L2 is emitted from a light source (not shown) disposed at a rear portion of the array substrate 200, and exits through the transmission window 251. As a result, image can be displayed.

The color filter substrate 100 includes the color fitter layer 120 a planarization layer 130 and a common electrode 140 that are successively formed on the second base substrate 110. The color filter layer 120 includes R, G and B color filters. Each of the R, G and B color fitters has first, second and third holes H1, H2 and H3, respectively. The first, second and third holes H1, H2 and H3 partially expose the second base substrate 110.

A portion of the color filter layer 120 in the reflection areas RA is removed by the first, second and third holes H1, H2 and H3. Accordingly, the probability that the external light L1 passes through the color filter layer 120 may be reduced, and thus the color reproducibility differences between the reflection areas RA and transmission areas TA are reduced,

Additionally, the size of the second holes H2 is larger than that of the first holes H1, and the size of the first holes H1 is larger than that of the third hole H3. Accordingly, the area of the G color filter is smaller than that of the R color filter, and the area of the R color filter is smaller than that of the B color filter. As a result, the color visibility differences between the R, G and B color pixels in the reflection areas RA are reduced.

The coordinates of white color are more sensitive to variations of the cell gap in the reflection mode, as compared to the transmission mode. Therefore, the step differences between the second base substrate 110 and color filter layer 120, which may occur in the reflection areas RA, are eliminated.

According to embodiments of the present invention, the planarization layer 130, which may be formed by a one-step exposing process that uses a mask having a transparent layer, a translucent layer and a shading layer may eliminate the step differences.

Accordingly, the LCD apparatus 400 may have a substantially uniform cell gap in the reflection areas RA, so that a display quality may be improved.

The color filter substrate in accordance with embodiments of the present invention includes color filters having at least one hole, so that the color reproducibility differences between a transmission area and a reflection area may be reduced and the color visibility differences between the color pixels may be reduced. Therefore, the display properties of the LCD apparatus may be improved.

Moreover, a planarization layer formed in the region where the holes are formed may eliminate a step difference that may occur between a color filter and the color filter substrate. Accordingly, the LCD apparatus may have a uniform cell gap in the reflection area.

Although the example embodiments of the present invention have been described it is understood that the present invention should not be limited to these example embodiments but various changes and modifications can be made by one ordinary skilled in the art within the spirit and scope of the present invention as hereinafter claimed.

What is claimed is:

1. A color filter substrate, comprising:
a plurality of first areas and a plurality of second areas;
a base substrate;
a color filter layer formed on the base substrate and including a plurality of color filters formed in the first and second areas, wherein at least one of the color filters formed in a second area has an opening that exposes a portion of the base substrate;
a planarization layer formed in the second areas, and
a transparent electrode covering the color filters formed in the first areas and the planarization layer formed in the second areas.

2. The color filter substrate of claim 1, wherein the planarization layer comprises an organic material.

3. The color filter substrate of claim 1, wherein the opening has a circular or a quadrilateral shape.

4. The color filter substrate of claim 1 wherein a size of the opening is equal to or less than half the size of the color filter formed in the second area.

5. The color filter substrate of claim 1, wherein the color filters formed in the first and second areas include red (R), green (G) and blue (B) color filters and each of the red (R), green (G) and blue (B) color filters formed in the second areas includes an opening exposing part of the base substrate in the second areas.

6. The color filter substrate of claim 5, wherein sizes of the openings formed in the red (R), green (G) and blue (B) color filters, respectively, are different from each other.

7. The color filter substrate of claim 6, wherein the size of the opening formed in the red (R) color filter is larger than the size of the opening formed in the blue (B) color filter, and the size of the opening formed in the green (G) color filter is larger than the size of the opening formed in the red (R) color filter.

8. The color filter substrate of claim 5, wherein the sizes of the openings formed in the red (R), green (G) and blue (B) color filters, respectively, are substantially the same, and numbers of the openings formed in the red (R), green (G) and blue (B) color filters, respectively, are different from each other.

9. The color filter substrate of claim 8, wherein the number of the openings formed in the red (R) color filter is more than the number of the openings formed in the blue (B) color filter and the number of the openings formed in the green (G) color filter is more than the number of the openings formed in the red (R) color filter.

10. The color filter substrate of claim 1 wherein the thickness of the color filters formed in the second areas is thinner than the thickness of the color filters formed in the first areas.

11. The color filter substrate of claim 10, the color filters formed in the first and second areas include red (R), green (G) and blue (B) color filters and the thicknesses of the red (R) green (G) and blue (B) color filters formed in the second areas are different from each other.

12. The color filter substrate of claim 11, wherein the thickness of the red (R) color filter is thinner than the thickness of the blue (B) color filter and the thickness of the green (G) color filter is thinner than the thickness of the red (R) color filter

13. The color fitter substrate of claim 1, wherein a first light that sequentially passes through the transparent electrode, the color fitter layer and the base substrate is provided to the first areas and
a second light that sequentially passes through the base substrate the color filter layer the transparent electrode the color filter layer and the base substrate is provided to the second areas.

14. A method of manufacturing a color filter substrate including a first area and a second area, the method comprising:
forming a color filter layer on the base substrate, the color filter layer including a plurality of color filters;
forming an opening in a color filter formed in the second area, the opening partially exposing the base substrate;
coating the color filter layer with an organic material;
exposing the organic material to light with a mask disposed over the organic material;
forming a planarization layer in the second area by developing the air organic material; and
forming a transparent electrode on the planarization layer and the color filter layer, respectively.

15. The method of claim 14, wherein the mask includes a transparent portion, a translucent portion, and a shading portion.

16. The method of claim 15, wherein an optical transmissivity of the translucent portion is in a range from about 10% to about 30%.

17. The method of claim 15, wherein the mask is disposed so that the shading portion corresponds to the opening of the color filter, the translucent portion corresponds to a region where the opening is not formed in the second area, and the transparent portion corresponds to the first area.

18. The method of claim 15, wherein the transparent portion, the translucent portion and the shading portion are formed at layers different from each other.

19. The method of claim 15, wherein the transparent portion, the translucent portion and the shading portion are formed at the same layer.

20. The method of claim 14, wherein the transparent electrode covers the color filter formed in the first area and the planarization layer formed in the second area, respectively.

21. A display apparatus comprising:
an array substrate including a first base substrate, a transmission electrode and a reflection electrode formed on the first base substrate, the array substrate defining transmission areas and reflection areas,
a color fitter substrate including first areas and second areas, the color filter substrate including:
a second base substrate;
a color filter layer formed on the second base substrate, the color filter layer including an opening formed in a second area, the opening partially exposing the second base substrate;
a planarization layer formed in the second areas; and
a transparent electrode formed on the color filter layer and the planarization layer, respectively, and
a liquid crystal layer interposed between the array substrate and the color filter substrate.

22. The display apparatus of claim 21, wherein the planarization layer comprises an organic material.

23. The display apparatus of claim 21, wherein the opening has a circular or a quadrilateral shape.

24. The display apparatus of claim 21, wherein the color fitter layer includes a plurality of color filters, and the opening is formed in at least one color filter formed in the second area,
wherein the size of the opening is equal to or less than half the size of the color filter formed in the second area.

25. The display apparatus of claim 21, wherein the first areas correspond to the transmission areas of the array substrate, and the second areas correspond to the reflection areas of the array substrate.

26. The display apparatus of claim 21, wherein a first light that sequentially passes through the transparent electrode, the color filter layer and the second base substrate is provided to the first areas, and
a second light that sequentially passes through the second base substrate, the color filter layer, the transparent electrode, the color filter layer and the second base substrate is provided to the second areas.

27. The display apparatus of claim 21, wherein the color filters formed in the first and second areas include red (R), green (G) and blue (B) color filters and each of the red (R), green (G) and blue (B) color filters formed in the second areas includes an opening that exposes part of the second base substrate in the second areas.

28. The display apparatus of claim 27, wherein the size of the opening formed in the red (R) color filter is larger than the size of the opening formed in the blue (B) color filter, and the size of the opening formed in the green (G) color filter is larger than the size of the opening formed in the red (R) color filter.

29. The display apparatus of claim 27, wherein the sizes of the openings formed in the red (R), green (G) and blue (B) color filters, respectively, are substantially the same,
wherein the number of the openings formed in the red (R) color fitter is more than the number of the openings formed in the blue (B) color fitter, and the number of the openings formed in the green (G) color fitter is more than the number of the openings formed in the red (R) color filter.

30. The display apparatus of claim 21. wherein the thickness of the color filters formed in the second areas is thinner than the thickness of the color fitters formed in the first areas.

31. The display apparatus of claim 30 wherein the color filters formed in the first and second areas include red (R), green (G) and blue (B) color fitters, and
wherein the thickness of the red (R) color fitter is thinner than the thickness of the blue (B) color filter, and the thickness of the green (G) color filter is thinner than the thickness of the red (R) color filter.
